(19) United States
(12) Patent Application Publication
(10) Pub. No.: US 2003/0235224 A1
(43) Pub. Date: Dec. 25, 2003

(54) Strained quantum-well structure having ternary-alloy material in both quantum-well layers and barrier layers

(76) Inventor: Ulf Roald Ohlander, Sverige (SE)

Correspondence Address: Ronald L. Grudziecki, Esq., BURNS, DOANE, SWECKER & MATHIS, L.L.P., P.O. Box 1404, Alexandria, VA, 22313-1404, US

(21) Appl. No.: 10/173,853

(22) Filed: Jun. 19, 2002

(51) Int. Cl. H01S 5/00

(52) U.S. Cl. 372/46

(57) ABSTRACT

A layer structure for use in a semiconductor laser is formed using semiconductor ternary-alloy materials comprising two elements categorized in the same column of the periodic table. The two elements are present in both the quantum-well layers and the barrier layers at the same composition ratio. The quantum-well layers and the barrier layers may be oppositely strained to provide strain compensation, yielding a total strain for the layer structure that is substantially zero or low enough to prevent relaxation. The layer structure provides good high-temperature performance, low threshold current, good reliability, and low complexity that facilitates strain compensation.

### BACKGROUND

1. Field of the Invention

The present invention relates to semiconductor lasers and, in particular, to semiconductor lasers having strained barrier layers and strained quantum-well (QW) layers.

2. Background Information

Semiconductor lasers are of considerable importance in many applications, particularly in fiberoptic communication networks where the lasers may be used as transmitters. In fiberoptic communication networks, semiconductor lasers having long-wavelength emission, i.e., on the order of 1-1.6 μm, are of interest. Wavelengths of 1.3 μm and 1.55 μm are particularly important for silica-based optical-fiber networks.

InP-based semiconductor lasers operating near 1.3 μm are expected to have considerable importance in future fiberoptic communication networks. However, before the potential for these lasers can be fully realized, InP-based lasers having low threshold current, good high-temperature performance, and good reliability (long-life) must be developed.

Methods for obtaining low threshold current and good reliability in InP-based lasers have been proposed in the literature. For example, as noted in the article “Low-Threshold (3.2 mA per Element) 1.3 μm InGaAsP MQW Laser Array on a p-Type Substrate” by Yamashita et al. (IEEE Photonics Tech. Lett. Vol. 4, No. 9, pp. 954-957 (1992)), threshold currents may be improved by utilizing short cavity lengths, high-reflection coatings, and multiple-quantum-well (MQW) structures, particularly MQW structures having strained QW layers.

If strained MQW structures are utilized in a semiconductor laser, it can be beneficial to engineer the QW layers and barrier layers with opposite strains to obtain good reliability (long life) as noted in the article “Long-term reliability of strain-compensated InGaAs(P)/InP MQW BH lasers” by Seltzer et al. (Electronics Lett. Vol. 30, No. 3, pp. 227-229 (1994)). Such strain compensation can prevent relaxation of the layer structure, which can otherwise cause crystal defects and device failure. Strain compensation can allow numerous strained QW layers and strained barrier layers to be utilized in an MQW laser while maintaining a reliable device.

Though the above-noted approaches may improve low threshold current and reliability in InP-based lasers, InP-based lasers continue to be plagued with poor performance at elevated temperatures. For example, the optical gain can decrease significantly with increasing temperature, and the threshold current can increase significantly with increasing temperature. As noted in the articles “Analysis of Temperature Dependent Optical Gain of Strained Quantum Well Taking Account of Carriers in the SCH Layer” by Ishikawa et al. (IEEE Photonics Tech. Lett. Vol. 6, No. 3, pp. 344-347 (1994)) and “Effect of Thermionic Electron Emission from the Active Layer on the Internal Quantum Efficiency of InGaAsP Lasers Operating at 1.3 μm” by Andrekson et al. (IEEE Journ. Quant. Elec. Vol. 30, No. 2, pp. 219-221 (1994)), the above-mentioned poor temperature characteristics are believed to be caused in part by poor carrier confinement (i.e., by carrier leakage). Improving carrier confinement in InP-based lasers by using layers with large barrier heights may improve the high-temperature performance of such lasers, as noted in the article “High-Temperature Operation of InGaAs/InGaAsP Compressive-Strained QW Lasers with Low Threshold Currents” by Nobuhara et al. (IEEE Photonics Tech. Lett. Vol. 5, No. 9, pp. 961-962 (1993)).

In “Temperature dependence of threshold current density Jₜₕ and differential efficiency η_{d} of high-power InGaAsP/GaAs (λ=0.8 μm) lasers” by Yi et al. (Appl. Phys. Lett. Vol. 66, No. 3, pp. 253-255 (1995)), an experimental and theoretical study on the temperature dependence of threshold current density and differential efficiency was described for certain GaAs-based lasers. Yi et al. disclosed that the major reason for increased threshold current density and decreased differential efficiency at high temperatures was thermal broadening of the gain spectrum, which results in reduction of the gain peak. However, Yi et al. further disclosed that the observed temperature dependence of the threshold current density and the differential efficiency could not be fully explained by thermal broadening of the gain spectrum. For the InGaAsP/GaAs lasers discussed therein, Yi et al. found that an increase in the momentum relaxation rate [symbol] /τ also contributed to the observed temperature dependence of the threshold current density and the differential efficiency and that the increase in the momentum relaxation rate [symbol] /τ mainly originated from alloy scattering. Alloy scattering refers to the scattering of carriers in alloys due to randomness in the placement of component atoms among the available lattice sites, such as noted in the article “Alloy scattering potential in p-type Ga₁₋ₓAlₓAs” by Masu et al. (Jour. App. Phys. Vol. 54, No. 10, pp. 5785-5792 (1983)).

### SUMMARY

Applicant has recognized that alloy scattering may be detrimental to the high-temperature performance of InP-based lasers and that increased disorder in the placement of component atoms on the available lattice sites can result in increased alloy scattering. The conventional InP-based lasers noted above utilize quaternary-alloy materials in the QW layer or the barrier layers (or both) and, and the use of such quaternary-alloy materials may exacerbate alloy scattering. It would be desirable to have an InP-based laser that operates at long wavelength, that incorporates a strained MQW structure to provide a low threshold current, that incorporates strain compensation to provide good reliability, and that provides good carrier confinement while simultaneously having reduced alloy scattering to enhance high-temperature performance. It would also be desirable to have a semiconductor laser with the above characteristics that is less complex than conventional long-wavelength semiconductor lasers and, accordingly, less costly to fabricate.

According to the present invention, there is provided a layer structure for use in a long-wavelength semiconductor laser that provides for low-threshold, long-wavelength operation with high reliability and good high-temperature performance. In addition, the present invention combines the benefits of strain compensation with reduced alloy scattering and can provide for less complexity and lower fabrication costs than are encountered for conventional long-wavelength semiconductor lasers.

In one aspect of the present invention, a structure in a semiconductor laser is provided. The structure comprises at least one quantum-well layer of a first semiconductor ternary-alloy material comprising two elements categorized in the same column of the periodic table of the elements. The structure further comprises a plurality of barrier layers of a second semiconductor ternary-alloy material comprising the same two elements. The two elements are provided at the same composition ratio in both the first and second semiconductor ternary-alloy materials. Each quantum-well layer is disposed between adjacent barrier layers. The two elements can be group-V elements.

In an exemplary aspect, the two elements can be As and P. In addition, the first ternary alloy can include In, and the second ternary alloy can include Ga. The quantum-well layer can comprise InAs_{0.45}P_{0.55}, and the barrier layers can comprise GaAs_{0.45}P_{0.55}.

In addition, the barrier layers and the quantum-well layer can be strained with opposite signs such that the structure is strain compensated. In particular, the quantum-well layer can be compressively strained such that the total strain from the quantum-well layer and the barrier layers is substantially zero. Further, the structure can be incorporated into a semiconductor laser having a substrate comprising InP. The structure can provide for light emission at a wavelength of substantially 1.3 μm.

In another aspect of the present invention, a multiple-quantum-well structure in a semiconductor laser is provided. The structure comprises a plurality of quantum-well layers of a first semiconductor ternary-alloy material and a plurality of barrier layers of a second semiconductor ternary-alloy material. The first and second semiconductor ternary alloy materials both comprise a first element and a second element, and the first and second elements are categorized in the same column of the periodic table of the elements. The first and second elements are provided at the same composition ratio in both the first and second semiconductor ternary-alloy materials.

The first and second elements can be group-V elements and in particular can be As and P. The quantum well layers can further comprise In, and the barrier layers can further comprise Ga. The quantum-well layers can comprise InAS_{0.45}P_{0.55}, and the barrier layers can comprise GaAs_{0.45}P_{0.55}. The barrier layers and quantum-well layers can be strained with opposite signs. In particular, the quantum-well layers can be compressively strained and the structure can be strain compensated. Further, the total strain from the quantum-well layers and barrier layers can be substantially zero. In addition, the structure can be incorporated into a semiconductor laser having an InP substrate. The structure can provide for light emission at a wavelength of substantially 1.3 μm.

In another aspect of the present invention, the above-mentioned multiple-quantum-well structure further comprises a plurality of spacer layers. Each quantum-well layer is disposed between a pair of adjacent barrier layers to form a plurality of three-layer structures wherein each spacer layer is disposed between a pair of adjacent three-layer structures.

In another aspect of the present invention, there is provided a method of fabricating a layer structure in a semiconductor laser. The method comprises providing a substrate, and forming at least one quantum-well layer of a first semiconductor ternary-alloy material and a plurality of barrier layers of a second semiconductor ternary-alloy material on the substrate. The first and second semiconductor ternary alloy materials both comprise a first element and a second element, the first and second elements being categorized in a same column of the periodic table of the elements. The first and second elements are provided at the same composition ratio in both the first and second semiconductor ternary-alloy materials.

It should be emphasized that the terms “comprises” and “comprising”, when used in this specification, are taken to specify the presence of stated features, integers, steps or components. However, the use of these terms does not preclude the presence or addition of one or more other features, integers, steps, components or groups thereof.

### BRIEF DESCRIPTION OF THE DRAWINGS

The foregoing and other objects, features and advantages of the present invention will be understood by reading the following detailed description in conjunction with the drawings.

FIG. 1 shows an exemplary layer structure comprising one QW layer and two barrier layers according to one aspect of the present invention.

FIG. 2 is an energy-level diagram for the structure shown in FIG. 1.

FIG. 3 shows an exemplary layer structure comprising a plurality of QW layers and a plurality of barrier layers according to another aspect of the present invention.

FIG. 4 is an energy-level diagram for the structure shown in FIG. 3.

FIG. 5 shows an exemplary layer structure comprising a plurality of QW layers and a plurality of barrier layers with intervening spacer layers according to another aspect of the present invention.

FIG. 6 shows a flow diagram for an exemplary method of making a layer structure according to the present invention.

### DETAILED DESCRIPTION

Various aspects of the invention will now be described with respect to the Figures. The invention can be used, for example, in semiconductor lasers of a fiberoptic communication network. However, the invention is not limited to this use, but can instead be used in a wide range of applications.

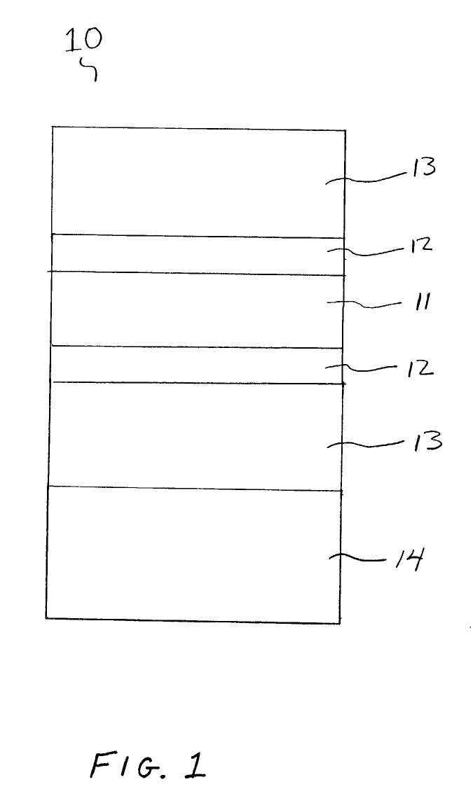

FIG. 1 illustrates an exemplary layer structure 10 for use in a semiconductor laser according to one aspect of the present invention. The structure 10 comprises at least one quantum-well (QW) layer 11 made of a first semiconductor ternary-alloy material and a plurality of barrier layers 12 made of a second semiconductor ternary-alloy material. Each QW layer 11 is disposed between adjacent barrier layers 12. The barrier layers 12 formed at opposing sides of the QW layer 11 confine carriers within the QW layer 11. The QW layer 11 and barrier layers 12 are formed on a substrate 14, which can be, for example, an InP substrate. Additional layers 13 (e.g., waveguide layers in which the laser radiation propagates) can be formed at outer surfaces of the barrier layers 12. For example, a bottom additional layer 13 can be formed between a bottom barrier layer 12 and the substrate 14. Not shown are additional layers such as cladding layers and electrodes, which can be conventionally provided in ways known to those skilled in the art. By utilizing ternary-alloy materials, the QW layer 11 and the barrier layer 12 have fewer elemental constituents than layers comprised of quaternary-alloy materials. In other words, the QW layer 11 and the barrier layers 12 have a reduced alloy number compared to layers comprising quaternary-alloy materials.

The first semiconductor ternary-alloy material and the second semiconductor ternary-alloy material each comprise two elements from the same column of the periodic table of the elements. Such elements may hereinafter be referred to as “same-group” elements. Further, the two elements are provided at the same composition ratio in both the first and second semiconductor ternary-alloy materials. The two elements can be group-V elements where group-V refers to the fifth column of the periodic table.

In the exemplary structure 10 illustrated in FIG. 1 the QW layer 11 and the barrier layers 12 can have opposite strains (relative to the substrate 14) and appropriate thicknesses such that effective strain compensation is achieved. In other words, though the QW layer 11 and the barrier layers 12 are strained, the amount of strain and the layer of thicknesses can be engineered such that the layer structure 10 does not relax (form dislocations). For example, according to one aspect of the present invention, the QW layer 11 can be compressively strained, and the barrier layers 12 can be strained in tension to balance the compressive strain in the QW layer 11. The strain of a layer multiplied by the thickness of that layer gives the total strain vector of that layer. Effective strain compensation can be achieved by alternating compressive and tensile strains between adjacent layers and by choosing appropriate strain magnitudes and layer thicknesses such that the total strain (sum of the strain vectors of the QW layer 11 and the barrier layer 12) of the layer structure 10 is substantially zero or low enough to prevent relaxation. Further, the thickness of the QW layer 11 and the barrier layers 12 can be chosen below an appropriate critical thickness for each layer such that relaxation of the layers does not occur during fabrication of the layer structure 10. Such strain compensation is known to those skilled in the art as described, for example, in “Design criteria for structurally stable, highly strained multiple quantum well devices” by D. C. Houghton et al. (Appl-Phys. Lett. Vol. 64, No. 4, pp. 505-507 (1994)).

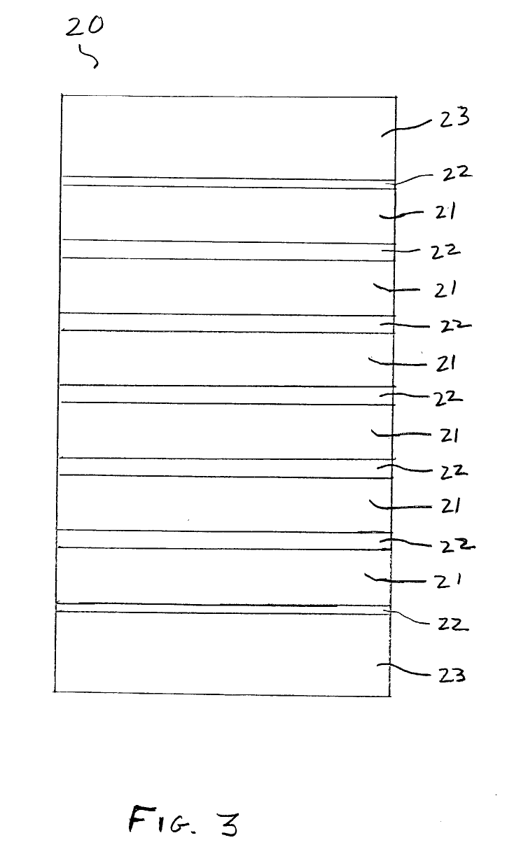

Such strain compensation provides for good device reliability (long life) and allows numerous quantum-well layers and barrier layers to be utilized, such as in an exemplary layer structure comprising multiple quantum wells according to the present invention as described below in relation to FIG. 3. Further, compressively straining the QW layer 11 can reduce the threshold current of an associated laser by decreasing the density of hole states within the QW layer. Lowering the density of hole states can allow a population inversion and lasing to be obtained at, a lower applied current, i.e., the threshold current can be reduced.

In an exemplary aspect relating to the exemplary layer structure 10 shown in FIG. 1, the additional layers 13 (e.g., waveguide layers) can be formed of InP. The additional layers 13 can be disposed at outer surfaces of two 1 nm thick ternary-alloy barrier layers 12 made of GaAs_{0.45}P_{0.55}. The barrier layers 12 can have a tensile strain (e.g., 5.5%) relative to an InP substrate (not shown). The barrier layers 12 are disposed at opposing surfaces of a 7 nm thick, compressively strained (e.g., 1.5%) ternary-alloy QW layer 11 made of InAs_{0.45}P_{0.55}. The As/P composition ratio of 0.45/0.55 is the same for both the QW layer 11 and barrier layers 12. Calculations indicate that transitions between heavy hole states and electron states can provide for output light emission at a wavelength of approximately 1.29 μm for a laser incorporating such a layer structure and fabricated on an InP substrate. Such light emission at substantially 1.3 μm is beneficial for optical communications.

As used in this specification, the term “ternary-alloy material” does not preclude the addition of dopants of other elements to make the ternary-alloy material p-type or n-type. Such doped ternary-alloy materials are considered ternary-alloy materials and as such can be used in making the layer structure according to the present invention.

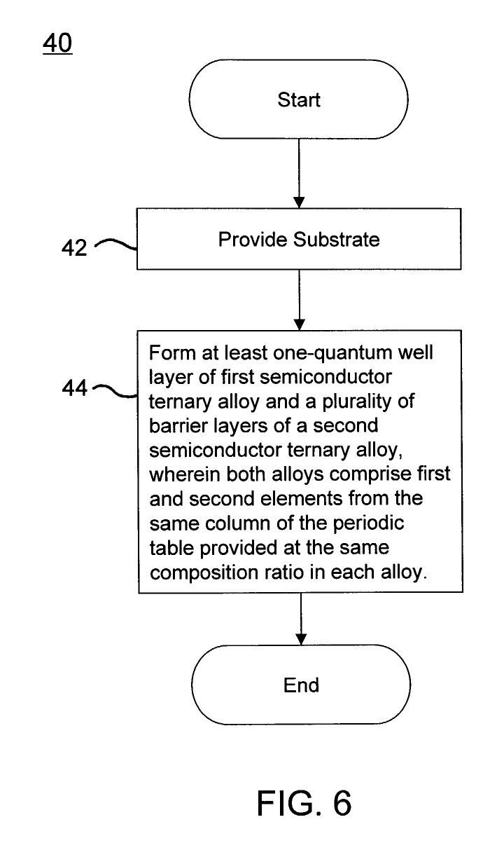

According to another aspect of the present invention, there is provided a method of fabricating a layer structure of a semiconductor laser. FIG. 6 illustrates an exemplary method 40 of fabricating a layer structure. Referring to FIG. 1 and FIG. 6, the method comprises providing a substrate 14 (step 42), and forming at least one QW layer 11 of a first semiconductor ternary-alloy material and a plurality of barrier layers 12 of a second semiconductor ternary-alloy material on the substrate 14 (step 44). The substrate 14 can be, for example, a p-doped or n-doped substrate and can be, for example, an InP substrate. The QW and barrier layers 11 and 12 can be formed using any appropriate technique such as molecular beam epitaxy (MBE), chemical vapor deposition (CVD), and liquid phase epitaxy (LPE) to name a few. These and other techniques are well known in the art and do not require further description. Multiple repeats of the QW layer 11 and the barrier layers 12 can be provided to form a MQW structure, such as illustrated with regard to the example of FIG. 3 described below. The QW layer(s) 11 and barrier layers 12 are formed such that the first and second semiconductor ternary alloy materials both comprise a first element and a second element, the first and second elements being categorized in the same column of the periodic table of the elements (step 44). In addition, the QW layer(s) 11 and barrier layers 12 are formed such that the first and second elements are provided at the same composition ratio in both the first and second semiconductor ternary-alloy materials (step 44).

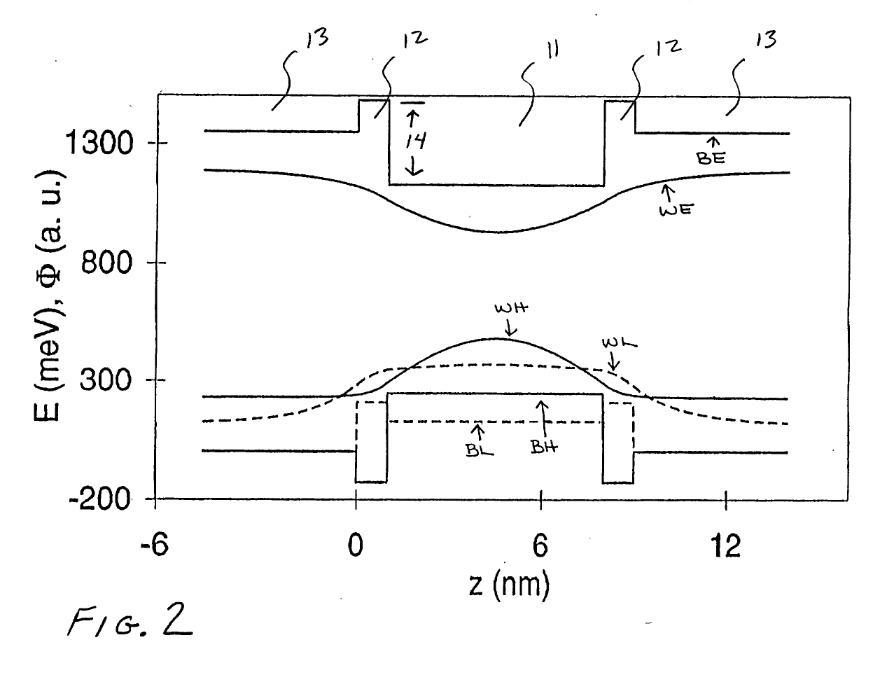

FIG. 2 shows an energy-band diagram for the exemplary structure 10 shown in FIG. 1 according to the present invention. In FIG. 2, BE denotes the energy-band edge (band edge) for electrons, BH denotes the band edge for heavy holes, BL denotes the band edge for light holes, WE denotes a ground-state wave function of an electron, WH denotes a ground-state wave function of a heavy hole, and WL denotes a ground-state wave function of a light hole. In FIG. 2, the barrier height is denoted by reference character 14. By virtue of barrier height 14, carriers (electrons and holes) can be predominantly contained within the QW layer. However, it is evident from FIG. 2 that the wave function WE of an electron and the wave functions WH and WL of holes can extend into the barrier layers 12. The significance of this observation will be further described below in relation to the design of the layer structure 10 to provide for reduced alloy scattering and improved high-temperature performance.

The present invention has advantages compared to conventional InP-based semiconductor lasers that use quaternary QW layers and barrier layers. First, by utilizing ternary-alloy material for the QW layer, the present invention reduces alloy scattering of carriers in the QW layer and thus provides for improved high-temperature performance compared to conventional quaternary InP-based lasers. For example, by reducing the number of atom types in the QW layer, the crystal lattice of the QW layer can more easily be fabricated with fewer defects, i.e., the imperfections in the crystal lattice can be reduced compared to conventional quaternary structures. With fewer imperfections in the crystal lattice, electrons and holes propagating through the lattice are less likely to be scattered, i.e., alloy scattering is reduced. By reducing alloy scattering, the exemplary structure 10 according to the present invention can provide improved high-temperature performance of an associated laser.

In addition, the present invention further reduces alloy scattering by forming the barrier layers 12 from ternary-alloy materials. As noted above with regard to FIG. 2, the wave functions of electrons and holes predominantly confined to the QW layer 11 can nevertheless penetrate into the barrier layers 12. Thus, the barrier layers 12 can, therefore, contribute to alloy scattering. Accordingly, the present invention further reduces the likelihood of such scattering by forming the barrier layers 12 of ternary-alloy materials. Thus, the present invention further provides for improved high-temperature performance of associated lasers.

Also, by utilizing ternary-alloy materials having two elements from the same column of the periodic table at the same composition ratio in both the QW layer 11 and the barrier layers 12, the present invention further reduces the likelihood of alloy scattering. In this manner, interdiffusion between the QW layer 11 and the barrier layers 12 can be minimized. For example, interdiffusion of group-V elements such as As and P can be substantially reduced compared to layer structures used in conventional InP-based lasers. Such interdiffusion is reduced in the present invention because the layer structure possesses no composition gradient of same-group elements to drive interdiffusion of those elements between the QW layer 11 and the barrier layers 12. In contrast, conventional InP-based lasers utilizing InGaAs QW layers and InGaAsP barrier layers, for example, show strong interdiffusion of the group-V elements As and P at elevated temperatures as reported in “Vacancy controlled interdiffusion of the group V sublattice in strained InGaAs/InGaAsP quantum wells” by Gillin et al. (Appl. Phys. Lett. Vol. 63, No. 6, pp. 797-799 (1993)). The exemplary layer structure 10 described above minimizes such interdiffusion by providing As and P at the same composition ratio in both the QW layer 11 and the barrier layers 12, thereby minimizing degradation in crystal quality and minimizing alloy scattering. Accordingly, the present invention is believed to have substantial advantages over structures utilized in conventional long-wavelength lasers including InP-based lasers.

In addition, minimizing interdiffusion improves the material quality and reliability of the QW layers 11 and barrier layers 12. Further, by utilizing QW layers 11 and barrier layers 12 made of ternary-alloy materials having two same-group elements at the same composition ratio, the present invention can facilitate strain compensation, for example, because the complexity of the layer structure is reduced.

FIG. 3 illustrates an exemplary multiple-quantum-well (MQW) structure 20 for use in a semiconductor laser according to another aspect of the invention. The QW layers 21 are disposed between barrier layers 22, which act to confine carriers in the QW layers 21. Also shown are additional layers 23 (e.g., waveguide layers). The QW layers 21 and the barrier layers 22 are made of first and second semiconductor ternary-alloy materials, respectively. The first and second semiconductor ternary-alloy materials include two elements from the same column of the periodic table (same-group elements), the two elements being provided at the same composition ratio in the QW layers 21 and the barrier layers 22. The two elements can be group-V elements.

The exemplary structure 20 of FIG. 3 can have opposite strains in the QW layers 21 and in the barrier layers 22 relative to a substrate (not shown). For example, the QW layers 21 can have a compressive strain. Compressive strain removes the energy degeneracy between light hole and heavy hole states, thereby reducing the density of hole states and thus reducing the threshold current of the laser. The overall structure 20 can be strain compensated as described in relation to the exemplary layer structure 10 illustrated in FIG. 1. As a result, a structure 20 with a large number of layers can be reliably produced and utilized.

The exemplary MQW structure 20 illustrated in FIG. 3 provides advantages compared to conventional quaternary InP-based semiconductor lasers such as discussed above in relation to the exemplary layer structure 10 illustrated in FIG. 1. In addition, the MQW structure 20 can also provide for increased optical gain compared to a comparable SQW structure.

In an exemplary aspect of the present invention relating to the exemplary layer structure 20 shown in FIG. 3, the additional layers 23 (e.g., waveguide layers) can comprise InP. The additional layers 23 can be disposed at outer surfaces of a superlattice of six QW layers 21 and corresponding barrier layers 22. The outermost barrier layers 22 adjacent to the top and bottom additional layers 23 can be made of 1 nm thick GaAs_{0.45}P_{0.55}. The inner barrier layers 22 can be made of 2 nm thick GaAs_{0.45}P_{0.55}. The barrier layers 22 can have a tensile strain (e.g., 5.5%) relative to an InP substrate. Pairs of barrier layers 22 can be disposed at opposing surfaces of 7 nm thick, compressively strained (e.g., 1.5%) QW layers 21 made of InAS_{0.45}P_{0.55}. The As/P composition ratio of 0.45/0.55 is the same for both the QW layers 21 and the barrier layers 22.

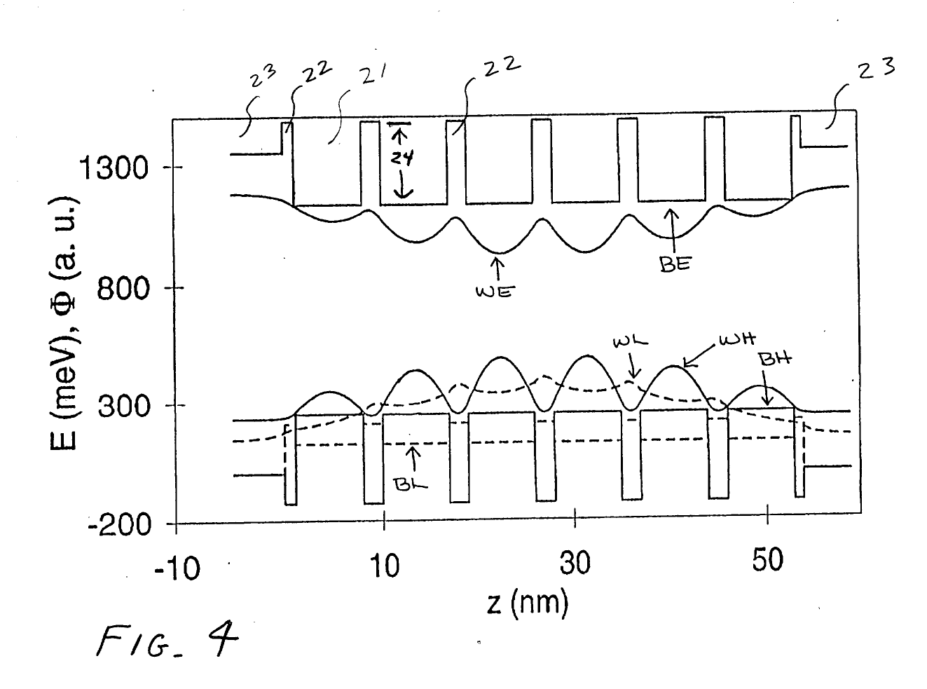

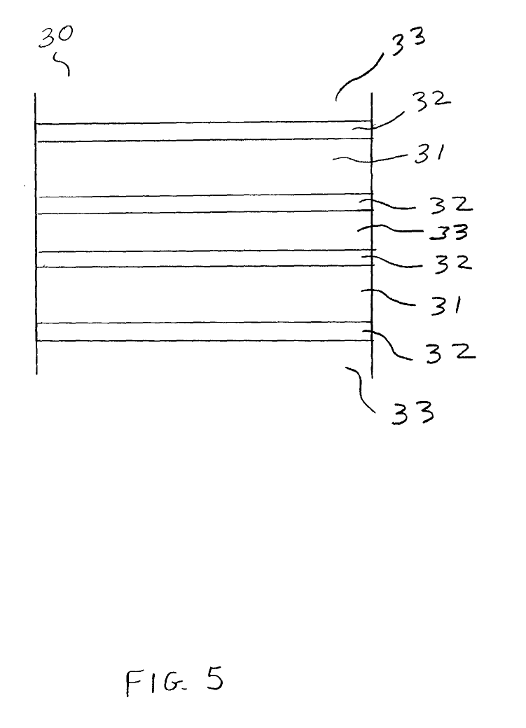

FIG. 4 shows an energy-band diagram for the exemplary MQW structure 20 of FIG. 3. In FIG. 4, BE denotes the band edge for electrons, BH denotes the band edge for heavy holes, and BL denotes the band edge for light holes. The barrier height is denoted by reference character 24. In addition, FIG. 4 also illustrates wave functions of electrons, heavy holes, and light holes, denoted as WE, WH and WL, respectively. The narrow separation between QW layers 21 provided by barrier layers 22 results in strong quantum-mechanical coupling between carriers in adjacent wells. This coupling is reflected by the shapes of the wave functions as illustrated in FIG. 4. Though there is strong coupling, the barrier height and thickness of the barrier layers 22 provide for substantial confinement of electrons and heavy holes, as evidenced by their corresponding wave functions. In addition, this coupling between carriers in adjacent wells causes light emission at a longer wavelength of 1.31 μm compared to 1.29 μm for the exemplary layer structure 10 illustrated in FIG. 1. The light emission at substantially 1.3 μm is advantageous for optical communication as noted previously. The extent of this coupling can be adjusted by including additional spacer layers as described below in relation to FIG. 5.

FIG. 5 illustrates a portion of an exemplary MQW structure 30 for use in a semiconductor laser according to another aspect of the invention. The exemplary MQW structure 30 is similar to that illustrated in FIG. 3 but provides additional spacer layers 33 to adjust the separation between adjacent QW layers 31. The QW layers 31 are disposed between barrier layers 32, which act to confine carriers in the QW layers 31. The QW layers 31 and the barrier layers 32 are made of first and second semiconductor ternary-alloy materials, respectively, as described in relation to the layer structure 20 illustrated in FIG. 3. The first and second ternary-alloy materials include two elements from the same column of the periodic table (same-group elements), the two elements being provided at the same composition ratio both the first and second ternary-alloy materials (i.e., in the QW layers 31 and the barrier layers 32). The two elements can be group-V elements. The structure 30 illustrated in FIG. 5 can be viewed as a plurality of three-layer structures separated by spacer layers 33 wherein each three-layer structure comprises a barrier layer 32, a QW layer 31 and another barrier layer 32.

If the spacer layer 33 is of sufficient thickness (e.g., 5-10 nm), it can substantially decouple the wave functions of carriers in adjacent QW layers 31. The extent of coupling between carriers of adjacent QW layers 31 can affect the densities of states of the carriers and can also affect the wavelength of the emitted light.

In an exemplary aspect of the present invention relating to the exemplary layer structure 30 shown in FIG. 5, a superlattice of six QW layers 31 and corresponding barrier layers 32 can be arranged between two additional InP layers (not shown), which can function, for example, as waveguide layers. The barrier layers 32 can be made of 2 nm thick GaAs_{0.45}P_{0.55} and can have a tensile strain (e.g., 5.5%) relative to an InP substrate (not shown). Pairs of barrier layers 32 can be disposed at opposing surfaces of 7 nm thick, compressively strained (e.g., 1.5%) QW layers 31 made of InAs_{0.45}P_{0.55}. The As/P composition ratio of 0.45/0.55 is the same for both the QW layers 31 and the barrier layers 32. In this exemplary aspect, the spacer layers 33 can be made of InP and can be 5-10 nm in thickness. Of course, other thicknesses for the spacer layers 33 can be used. Spacer layers 33 approximately 5-10 nm in thickness can substantially decouple the carriers in adjacent QW layers 31 given barrier layers 32 with thicknesses of 2 nm. Those skilled in the art will recognize that the thicknesses of the barrier layers 32 can also affect the coupling between carriers in adjacent QW layers 31.

The invention has been described with reference to particular embodiments. However, it will be readily apparent to those skilled in the art that it is possible to embody the invention in specific forms other than those described above. This can be done without departing from the spirit of the invention. The embodiments described herein are merely illustrative and should not be considered restrictive in any way. The scope of the invention is given by the appended claims, rather than the preceding description, and all variations and equivalents that fall within the range of the claims are intended to be embraced therein.

What is claimed is:

1. In a semiconductor laser, a structure comprising:
at least one quantum-well layer of a first semiconductor ternary-alloy material comprising two elements categorized in a same column of the periodic table of the elements; and
a plurality of barrier layers of a second semiconductor ternary-alloy material comprising the two elements,
wherein the two elements are provided at a same composition ratio in both the first and second semiconductor ternary-alloy materials, and
wherein each quantum-well layer is disposed between adjacent barrier layers.

2. The structure of claim 1, wherein the two elements are group-V elements.

3. The structure of claim 2, wherein the two elements are As and P.

4. The structure of claim 3, wherein the at least one quantum-well layer comprises InAs_{0.45}P_{0.55} and wherein the barrier layers comprise GaAs_{0.45}P_{0.55} .

5. The structure of claim 1, wherein the first semiconductor ternary-alloy material includes In and wherein the second semiconductor ternary-alloy material includes Ga.

6. The structure of claim 1, wherein the barrier layers and the at least one quantum-well layer are strained with opposite signs and wherein the structure is strain compensated.

7. The structure of claim 6, wherein the at least one quantum-well layer is compressively strained and wherein a total strain from the at least one quantum-well layer and the barrier layers is substantially zero.

8. The structure of claim 1, wherein the at least one quantum-well layer and the barrier layers are incorporated into a semiconductor laser having a substrate comprising InP, and wherein the structure can provide for light emission at a wavelength of substantially 1.3 μm.

9. In a semiconductor laser, a multiple-quantum-well structure, comprising:
a plurality of quantum-well layers of a first semiconductor ternary-alloy material; and
a plurality of barrier layers of a second semiconductor ternary-alloy material,
wherein the first and second semiconductor ternary alloy materials both comprise a first element and a second element, the first and second elements being categorized in a same column of the periodic table of the elements, and
wherein the first and second elements are provided at a same composition ratio in both the first and second semiconductor ternary-alloy materials.

10. The structure of claim 9, wherein the first and second elements are group-V elements.

11. The structure of claim 10, wherein the first and second elements are As and P, respectively.

12. The structure of claim 11, wherein the quantum-well layers further comprise In and wherein the barrier layers further comprise Ga.

13. The structure of claim 11, wherein the quantum-well layers comprise InAs_{0.45}P_{0.55} and wherein the barrier layers comprise GaAs_{0.45}P_{0.55}.

14. The structure of claim 9, wherein the barrier layers and the quantum-well layers are strained with opposite signs.

15. The structure of claim 14, wherein the quantum-well layers are compressively strained.

16. The structure of claim 15, wherein the structure is strain compensated.

17. The structure of claim 16, wherein a total strain from the quantum-well layers and the barrier layers is substantially zero.

18. The structure of claim 9, wherein the quantum-well layers and the barrier layers are incorporated into a semiconductor laser having an InP substrate, and wherein the structure can provide for light emission at a wavelength of substantially 1.3 μm.

19. The structure of claim 9, further comprising a plurality of spacer layers, wherein each quantum-well layer is disposed between a pair of adjacent barrier layers to form a plurality of three-layer structures and wherein each spacer layer is disposed between a pair of adjacent three-layer structures.

20. A method of fabricating a layer structure of a semiconductor laser, the method comprising:
providing a substrate; and
forming at least one quantum-well layer of a first semiconductor ternary-alloy material and a plurality of barrier layers of a second semiconductor ternary-alloy material on the substrate,
wherein the first and second semiconductor ternary alloy materials both comprise a first element and a second element, the first and second elements being categorized in a same column of the periodic table of the elements, and
wherein the first and second elements are provided at a same composition ratio in both the first and second semiconductor ternary-alloy materials.

21. The method of claim 20, wherein the two elements are group-V elements.

22. The method of claim 21, wherein the two elements are As and P.

23. The method of claim 22, wherein the at least one quantum-well layer comprises InAS_{0.45}P_{0.55} and wherein the barrier layers comprise GaAs_{0.45}P_{0.55}.

24. The method of claim 20, wherein the first semiconductor ternary-alloy material includes In and wherein the second semiconductor ternary-alloy material includes Ga.

25. The method of claim 20, wherein the barrier layers and the at least one quantum-well layer are formed with strains of opposite signs and wherein the barrier layers and the quantum-well layer form a structure that is strain compensated.

26. The method of claim 25, wherein the at least one quantum-well layer is compressively strained and wherein a total strain from the at least one quantum-well layer and the barrier layers is substantially zero.

27. The method of claim 20, wherein the substrate comprises InP, and wherein the barrier layers and the at least one quantum-well layer form a structure that can provide for light emission at a wavelength of substantially 1.3 μm.
